(19) United States
(12) Patent Application Publication
(10) Pub. No.: US 2026/0101462 A1
(43) Pub. Date: Apr. 9, 2026

(54) HOUSEHOLD APPLIANCE CIRCUIT BOARD HOUSING

(71) Applicant: Haier US Appliance Solutions, Inc., Wilmington, DE (US)

(72) Inventor: Tanner Davis Gunn, Louisville, KY (US)

(21) Appl. No.: 18/908,974

(22) Filed: Oct. 8, 2024

(51) Int. Cl. H05K 7/14

(52) U.S. Cl. CPC H05K 7/1427; H05K 7/1407; H05K 7/1405

(57) ABSTRACT

A circuit board assembly for a household appliance includes a circuit board housing and a circuit board. The circuit board housing is configured to be mounted within a cabinet of the household appliance. The circuit board housing includes a plurality of walls and an internal volume defined within the plurality of walls. The circuit board housing also includes a keep out feature and a boss configured to receive a fastener. The circuit board is retained in the internal volume of the circuit board housing between the plurality of walls. The keep out feature includes a rib integrally joined with one wall of the plurality of walls. The rib is configured to permit access by a driver to the boss of the housing while limiting access by the driver to the circuit board.

### FIELD OF THE INVENTION

The present subject matter relates generally to household appliances, such as washing machine appliances, and more particularly to control boards for such appliances.

### BACKGROUND OF THE INVENTION

Household appliances are utilized generally for a variety of tasks by a variety of users. For example, a household may include such appliances as laundry appliances, e.g., a washing machine appliance and/or dryer appliance, kitchen appliances, e.g., an oven appliance, a dishwasher appliance, etc., along with other various appliances. Such appliances generally include various electronic and mechanical components which are operated by a controller, where the controller includes one or more boards, e.g., circuit boards, housed within the appliance.

As mentioned, washing machine appliances are one example type of such household appliances. Washing machine appliances generally include a cabinet with a wash tub therein for containing water or wash fluid (e.g., water and detergent, bleach, or other wash additives). The wash tub may be suspended within the cabinet by a suspension system to allow some movement relative to the cabinet during operation. A basket is rotatably mounted within the wash tub and defines a wash chamber for receipt of articles for washing. During operation of such washing machine appliances, the wash fluid is directed into the wash tub and onto articles within the wash chamber of the basket. A drive assembly is coupled to the wash tub and configured to rotate the wash basket within the wash tub to agitate articles within the wash chamber, to wring wash fluid from articles within the wash chamber, etc.

At various times throughout the life of a household appliance, such as during the operation of the household appliance, the components of the appliance, such as one or more circuit boards, may be subjected to dynamic loads and/or vibration. For instance, referring again to the example washing machine appliance described above, rotation of the basket, particularly at high speeds, may induce dynamic loads and/or vibration. The household appliance components, e.g., circuit boards, may also be subjected to such loads and/or vibration at other times during the life of the household appliance, such as during shipping and handling of the household appliance. In order to secure the circuit board, e.g., to protect the circuit board as well as electrical connections on and to the circuit board from such vibrations, the circuit board may be mounted within a housing, such as secured with one or more mechanical fasteners. Installation of the circuit board within such housings may, however, potentially damage the circuit board, such as if a driver slips while driving the mechanical fastener and the driver impacts the circuit board.

Accordingly, improved housings for circuit boards in a household appliance are desired. In particular, housings which secure and protect the circuit board during installation into the household appliance and operation of the household appliance would be useful.

### BRIEF DESCRIPTION OF THE INVENTION

Aspects and advantages of the invention will be set forth in part in the following description, or may be obvious from the description, or may be learned through practice of the invention.

In one exemplary aspect of the present disclosure, a household appliance is provided. The household appliance includes a cabinet, and a circuit board housing mounted within the cabinet. The circuit board housing includes a plurality of walls and an internal volume defined within the plurality of walls. The circuit board housing also includes a keep out feature and a boss configured to receive a fastener. A circuit board is retained in the internal volume of the circuit board housing between the plurality of walls. The keep out feature includes a rib integrally joined with one wall of the plurality of walls. The rib is configured to permit access by a driver to the boss of the housing while limiting access by the driver to the circuit board.

In another exemplary aspect of the present disclosure, a circuit board assembly for a household appliance is provided. The household appliance includes a cabinet. The circuit board assembly includes a circuit board housing configured to be mounted within the cabinet. The circuit board housing includes a plurality of walls and an internal volume defined within the plurality of walls. The circuit board housing also includes a keep out feature and a boss configured to receive a fastener. The circuit board assembly also includes a circuit board retained in the internal volume of the circuit board housing between the plurality of walls. The keep out feature includes a rib integrally joined with one wall of the plurality of walls. The rib is configured to permit access by a driver to the boss of the housing while limiting access by the driver to the circuit board.

These and other features, aspects and advantages of the present invention will become better understood with reference to the following description and appended claims. The accompanying drawings, which are incorporated in and constitute a part of this specification, illustrate embodiments of the invention and, together with the description, serve to explain the principles of the invention.

### BRIEF DESCRIPTION OF THE DRAWINGS

A full and enabling disclosure of the present invention, including the best mode thereof, directed to one of ordinary skill in the art, is set forth in the specification, which makes reference to the appended figures.

FIG. 1 provides a perspective view of a washing machine appliance according to exemplary embodiments of the present disclosure.

FIG. 2 provides a cross-sectional side view of the exemplary washing machine appliance.

FIG. 3 provides a top view of an exemplary circuit board assembly for a household appliance according to one or more embodiments of the present disclosure.

FIG. 4 provides a perspective view of a portion of the housing from the assembly of FIG. 3.

FIG. 5 provides a bottom view of a portion of the housing from the assembly of FIG. 3.

FIG. 6 provides a side section view of the assembly of FIG. 3 in a partially installed configuration.

FIG. 7 provides a section view of a portion of the assembly of FIG. 3.

FIG. 8 provides a perspective view of a portion of the assembly of FIG. 3.

FIG. 9 provides another perspective view of a portion of the assembly of FIG. 3.

FIG. 10 provides yet another perspective view of a portion of the assembly of FIG. 3.

FIG. 11 provides a top view of a portion of the assembly of FIG. 3 in a partially installed configuration.

FIG. 12 provides a top view of the portion illustrated in FIG. 11 in a subsequent partially installed configuration.

FIG. 13 provides a section view of a portion of the assembly of FIG. 3 according to one or more additional exemplary embodiments of the present disclosure.

Repeat use of reference characters in the present specification and drawings is intended to represent the same or analogous features or elements of the present invention.

### DETAILED DESCRIPTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment can be used with another embodiment to yield a still further embodiment. Thus, it is intended that the present invention covers such modifications and variations as come within the scope of the appended claims and their equivalents.

In order to aid understanding of this disclosure, several terms are defined below. The defined terms are understood to have meanings commonly recognized by persons of ordinary skill in the arts relevant to the present invention. The terms “includes” and “including” are intended to be inclusive in a manner similar to the term “comprising.” Similarly, the term “or” is generally intended to be inclusive (i.e., “A or B” is intended to mean “A or B or both”). The terms “first,” “second,” and “third” may be used interchangeably to distinguish one element from another and are not intended to signify location or importance of the individual elements. Terms such as “inner” and “outer” refer to relative directions with respect to the interior and exterior of the washing machine appliance, and in particular the wash basket therein. For example, “inner” or “inward” refers to the direction towards the interior of the washing machine appliance. Terms such as “left,” “right,” “front,” “back,” “top,” or “bottom” are used with reference to the perspective of a user accessing the washing machine appliance. For example, a user stands in front of the washing machine appliance to open the door and reaches into the wash basket to access items therein. Furthermore, it should be appreciated that as used herein, terms of approximation, such as “approximately,” “substantially,” or “about,” refer to being within ten percent greater or less than the stated value. When used in the context of an angle or direction, such terms include within ten degrees greater or less than the stated angle or direction. For example, “generally vertical” includes directions within ten degrees of vertical in any direction, e.g., clockwise or counter-clockwise.

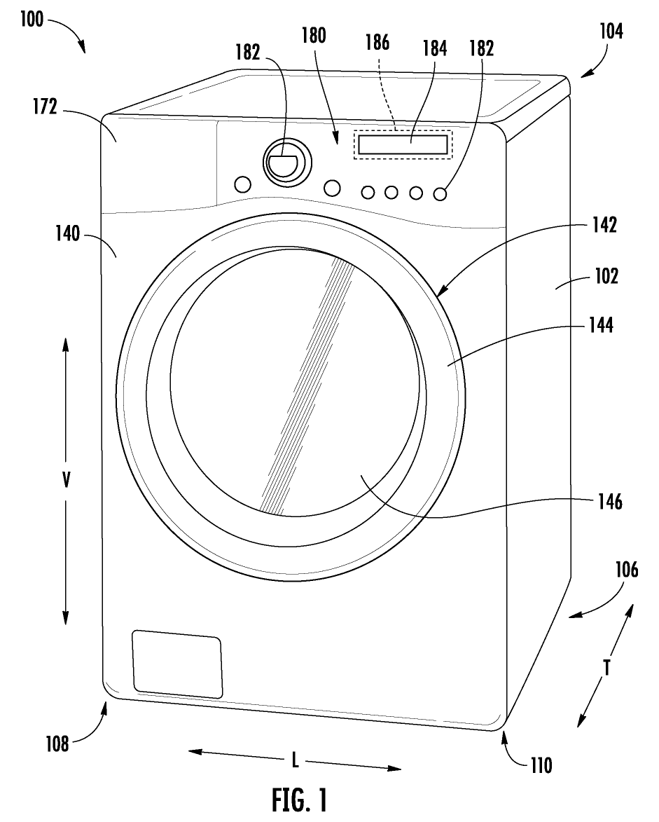

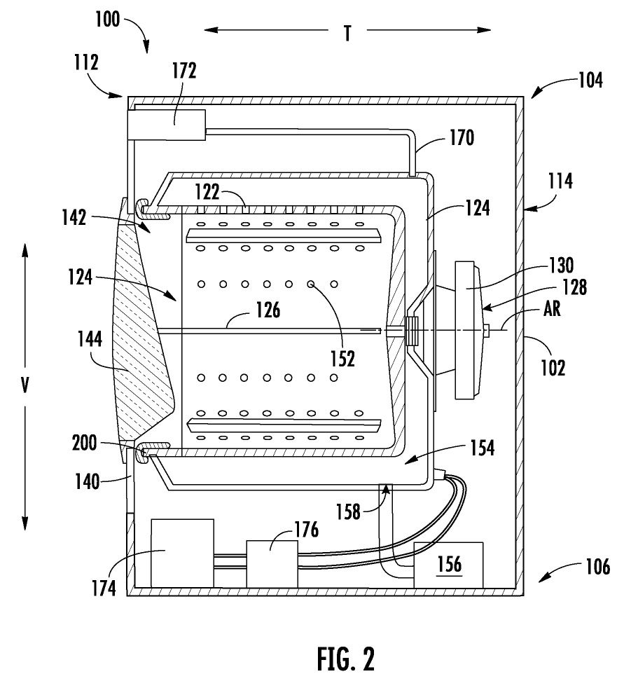

Referring now to the figures, FIG. 1 is a perspective view of an exemplary horizontal axis washing machine appliance 100 and FIG. 2 is a side cross-sectional view of washing machine appliance 100. As illustrated, washing machine appliance 100 generally defines a vertical direction V, a lateral direction L, and a transverse direction T, each of which is mutually perpendicular, such that an orthogonal coordinate system is generally defined. Washing machine appliance 100 includes a cabinet 102 that extends between a top 104 and a bottom 106 along the vertical direction V, between a left side 108 and a right side 110 along the lateral direction L, and between a front 112 and a rear 114 along the transverse direction T.

Referring to FIG. 2, a wash tub 120 is positioned within cabinet 102 and is generally configured for retaining wash fluids during an operating cycle. As used herein, “wash fluid” may refer to water, detergent, fabric softener, bleach, or any other suitable wash additive or combination thereof. A wash basket 122 is received within wash tub 120 and defines a wash chamber 124 that is configured for receipt of articles for washing. More specifically, wash basket 122 is rotatably mounted within wash tub 120 such that it is rotatable about an axis of rotation AR. According to the illustrated embodiment, the axis of rotation is substantially parallel to the transverse direction T. In this regard, washing machine appliance 100 is generally referred to as a “horizontal axis” or “front load” washing machine appliance 100. However, it should be appreciated that aspects of the present subject matter may be used within the context of a vertical axis or top load washing machine appliance as well.

Wash basket 122 may define one or more agitator features that extend into wash chamber 124 to assist in agitation and cleaning articles disposed within wash chamber 124 during operation of washing machine appliance 100. For example, as illustrated in FIG. 2, a plurality of ribs 126 extends from basket 122 into wash chamber 124. In this manner, for example, ribs 126 may lift articles disposed in wash basket 122 during rotation of wash basket 122.

Washing machine appliance 100 includes a drive assembly 128 which is coupled to wash tub 120 and is generally configured for rotating wash basket 122 during operation, e.g., such as during an agitation or spin cycle. More specifically, as best illustrated in FIG. 2, drive assembly 128 may include a motor assembly 130 that is in mechanical communication with wash basket 122 to selectively rotate wash basket 122 (e.g., during an agitation or a rinse cycle of washing machine appliance 100). According to the illustrated embodiment, motor assembly 130 is a pancake motor. However, it should be appreciated that any suitable type, size, or configuration of motors may be used to rotate wash basket 122 according to alternative embodiments. In addition, drive assembly 128 may include any other suitable number, types, and configurations of support bearings or drive mechanisms.

Referring generally to FIGS. 1 and 2, cabinet 102 also includes a front panel 140 that defines an opening 142 that permits user access to wash basket 122. More specifically, washing machine appliance 100 includes a door 144 that is positioned over opening 142 and is rotatably mounted to front panel 140 (e.g., about a door axis that is substantially parallel to the vertical direction V). In this manner, door 144 permits selective access to opening 142 by being movable between an open position (not shown) facilitating access to a wash tub 120 and a closed position (FIG. 1) prohibiting access to wash tub 120. A gasket 200 may be provided in the opening 142 and the gasket 200 may sealingly engage the door 144 when the door 144 is in the closed position. For example, the gasket 200 may extend between the tub 120 and the front panel 140, e.g., generally along the transverse direction T and may extend about or around the opening 142 such that the gasket 200 is covered by the door 144 when the door 144 is in the closed position, and the gasket 200 may promote sealing between the door 144 and the cabinet 102, e.g., the front panel 140 of the cabinet 102.

In some embodiments, a window 146 in door 144 permits viewing of wash basket 122 when door 144 is in the closed position (e.g., during operation of washing machine appliance 100). Door 144 also includes a handle (not shown) that, for example, a user may pull when opening and closing door 144. Further, although door 144 is illustrated as mounted to front panel 140, it should be appreciated that door 144 may be mounted to another side of cabinet 102 or any other suitable support according to alternative embodiments.

Referring again to FIG. 2, wash basket 122 also defines a plurality of perforations 152 in order to facilitate fluid communication between an interior of basket 122 and wash tub 120. A sump 154 is defined by wash tub 120 at a bottom of wash tub 120 along the vertical direction V. Thus, sump 154 is configured for receipt of, and generally collects, wash fluid during operation of washing machine appliance 100. For example, during operation of washing machine appliance 100, wash fluid may be urged (e.g., by gravity) from basket 122 to sump 154 through the plurality of perforations 152. A pump assembly 156 is located beneath wash tub 120 for gravity assisted flow when draining wash tub 120 (e.g., via a drain 158). Pump assembly 156 is also configured for recirculating wash fluid within wash tub 120.

Referring still to FIGS. 1 and 2, in some embodiments, washing machine appliance 100 may include an additive dispenser or spout 170. For example, spout 170 may be in fluid communication with a water supply (not shown) in order to direct fluid (e.g., clean water) into wash tub 120. Spout 170 may also be in fluid communication with the sump 154. For example, pump assembly 156 may direct wash fluid disposed in sump 154 to spout 170 in order to circulate wash fluid in wash tub 120.

As illustrated, a detergent drawer 172 may be slidably mounted within front panel 140. Detergent drawer 172 receives a wash additive (e.g., detergent, fabric softener, bleach, or any other suitable liquid or powder) and directs the fluid additive to wash chamber 124 during operation of washing machine appliance 100. According to the illustrated embodiment, detergent drawer 172 may also be fluidly coupled to spout 170 to facilitate the complete and accurate dispensing of wash additive.

In some embodiments, an optional bulk reservoir 174 may be disposed within cabinet 102. Bulk reservoir 174 may be configured for receipt of fluid additive for use during operation of washing machine appliance 100. Moreover, bulk reservoir 174 may be sized such that a volume of fluid additive sufficient for a plurality or multitude of wash cycles of washing machine appliance 100 (e.g., five, ten, twenty, fifty, or any other suitable number of wash cycles) may fill bulk reservoir 174. Thus, for example, a user can fill bulk reservoir 174 with fluid additive and operate washing machine appliance 100 for a plurality of wash cycles without refilling bulk reservoir 174 with fluid additive. A reservoir pump 176 may be configured for selective delivery of the fluid additive from bulk reservoir 174 to wash tub 120.

A control panel 180 including a plurality of input selectors 182 may be coupled to front panel 140. Control panel 180 and input selectors 182 collectively form a user interface input for operator selection of machine cycles and features. A display 184 of control panel 180 indicates selected features, operation mode, a countdown timer, and/or other items of interest to appliance users regarding operation.

Operation of washing machine appliance 100 is controlled by a processing device or a controller 186 that is operatively coupled to control panel 180 for user manipulation to select washing machine cycles and features. In response to user manipulation of control panel 180, controller 186 operates the various components of washing machine appliance 100 to execute selected machine cycles and features. Controller 186 may include a memory and microprocessor, such as a general or special purpose microprocessor operable to execute programming instructions or micro-control code associated with methods described herein. The memory may represent random access memory such as DRAM, or read only memory such as ROM or FLASH. In one embodiment, the processor executes programming instructions stored in memory. The memory may be a separate component from the processor or may be included onboard within the processor. Alternatively, controller 186 may be constructed without using a microprocessor, e.g., using a combination of discrete analog and/or digital logic circuitry (such as switches, amplifiers, integrators, comparators, flip-flops, AND gates, and the like) to perform control functionality instead of relying upon software. Control panel 180 may be in communication with controller 186 via one or more signal lines or shared communication busses to provide signals to and/or receive signals from the controller 186.

In exemplary embodiments, during operation of washing machine appliance 100, laundry items are loaded into wash basket 122 through opening 142, and a wash operation is initiated through operator manipulation of input selectors 182. For example, a wash cycle may be initiated such that wash tub 120 is filled with water, detergent, or other fluid additives (e.g., via detergent drawer 172 or bulk reservoir 174). One or more valves (not shown) can be controlled by washing machine appliance 100 to provide for filling wash basket 122 to the appropriate level for the amount of articles being washed or rinsed. By way of example, once wash basket 122 is properly filled with fluid, the contents of wash basket 122 can be agitated (e.g., with ribs 126) for an agitation phase of laundry items in wash basket 122. During the agitation phase, the basket 122 may be motivated about the axis of rotation AR at a set speed (e.g., first speed or tumble speed). As the basket 122 is rotated, articles within the basket 122 may be lifted and permitted to drop therein.

After the agitation phase of the washing operation is completed, wash tub 120 can be drained, e.g., by drain pump assembly 156. Laundry articles can then be rinsed (e.g., through a rinse cycle) by again adding fluid to wash tub 120, depending on the particulars of the cleaning cycle selected by a user. Ribs 126 may again provide agitation within wash basket 122. One or more spin cycles may also be used. In particular, a spin cycle may be applied after the wash cycle or after the rinse cycle in order to wring wash fluid from the articles being washed. During a spin cycle, basket 122 is rotated at relatively high speeds. For instance, basket 122 may be rotated at one set speed (e.g., second speed or pre-plaster speed) before being rotated at another set speed (e.g., third speed or plaster speed). As would be understood, the pre-plaster speed may be greater than the tumble speed and the plaster speed may be greater than the pre-plaster speed. Moreover, agitation or tumbling of articles may be reduced as basket 122 increases its rotational velocity such that the plaster speed maintains the articles at a generally fixed position relative to basket 122. After articles disposed in wash basket 122 are cleaned (or the washing operation otherwise ends), a user can remove the articles from wash basket 122 (e.g., by opening door 144 and reaching into wash basket 122 through opening 142).

During such operations, a gasket 200 may help to contain wash fluid within the cabinet 102, particularly within the tub 120. As generally shown in FIG. 2, the gasket 200 may be positioned between the door 144 and the tub 120, e.g., when the door 144 is in the closed position as in FIG. 2. Thus, the gasket 200 may sealingly engage the door 144 when the door 144 is in the closed position. In general, the gasket 200 sealingly engages the cabinet 102, in particular the opening 142 thereof, the tub 120, and the door 144. For example, the gasket 200 may extend around the opening 142 along a circumferential direction and may extend between the cabinet 102 and the wash tub 120 along an axial direction.

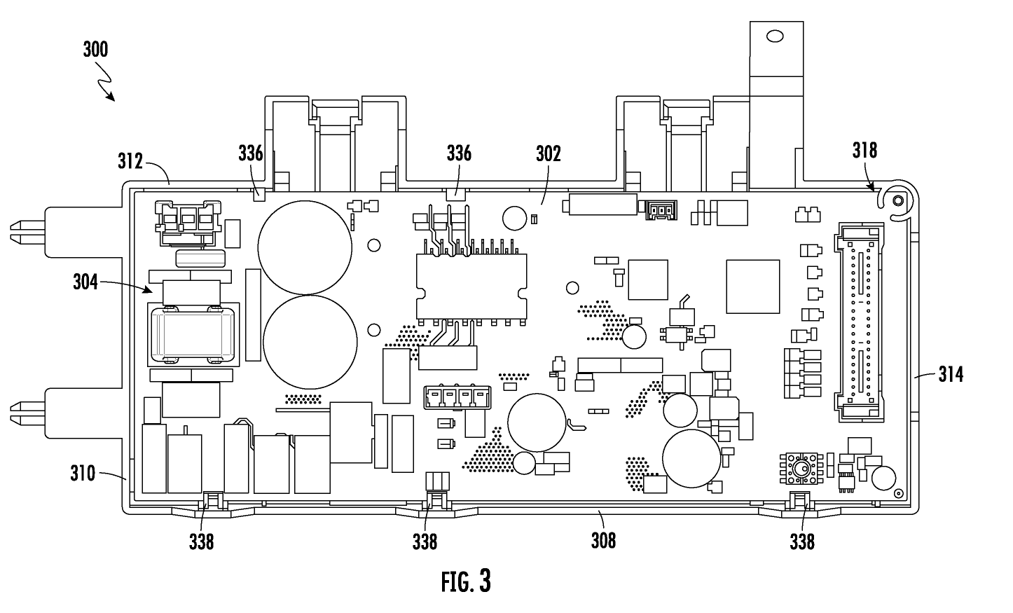

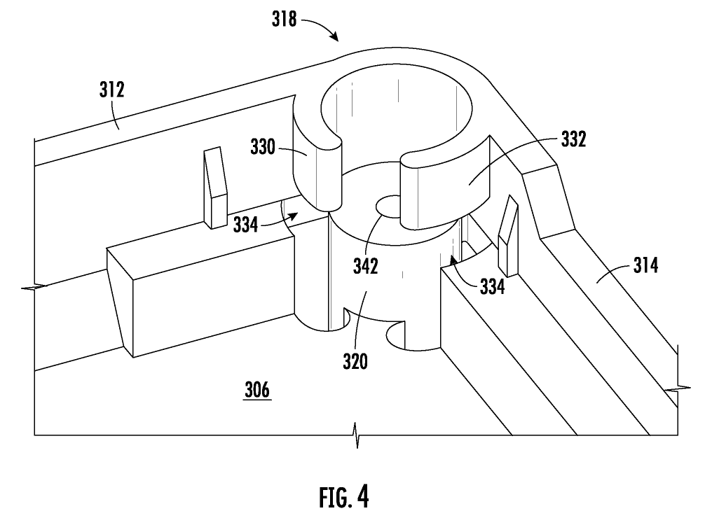

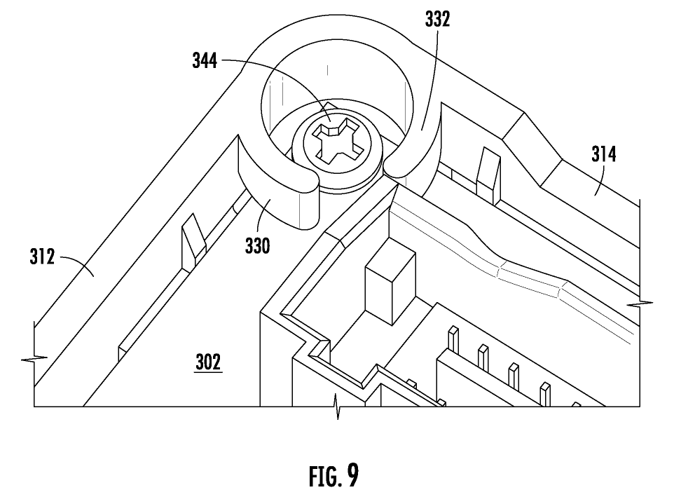

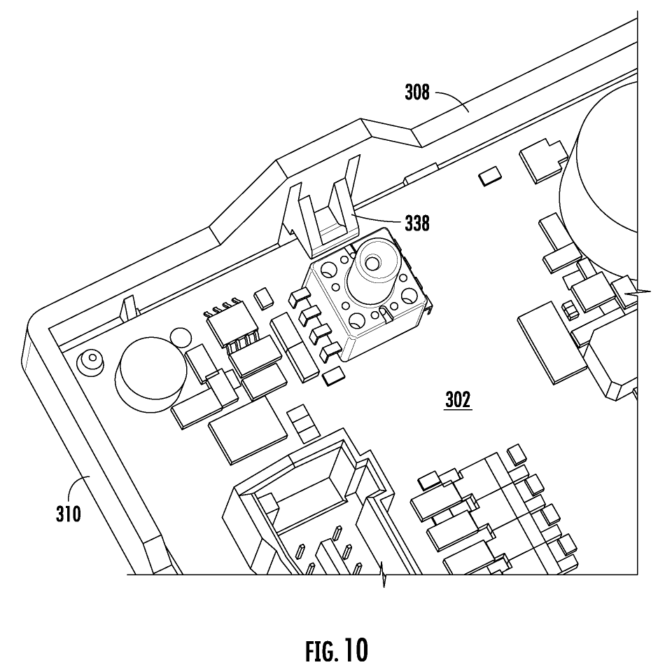

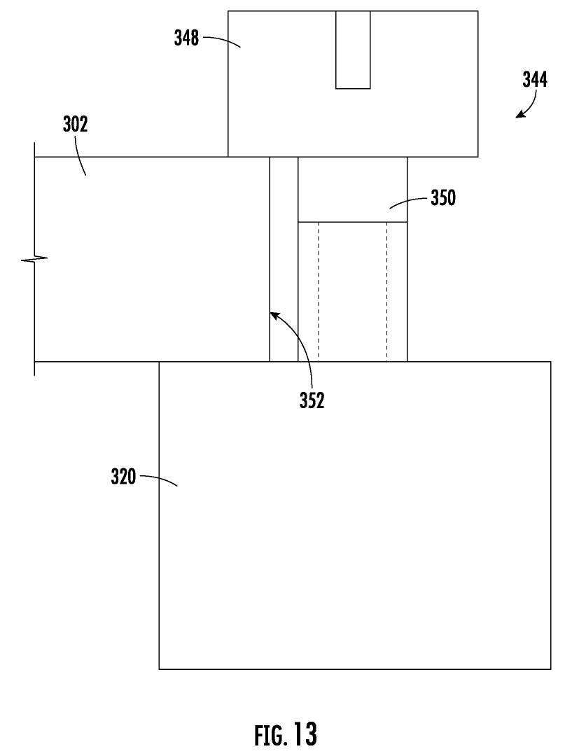

FIG. 3 provides a top view of a circuit board assembly including a circuit board housing 300 with a circuit board 302, e.g., a printed circuit board (“PCB”), retained therein. The circuit board 302 may be any suitable circuit board for use within a household appliance such as the exemplary washing machine appliance 100 described above. For example, circuit board 302 may be the controller 186 or a portion of the controller 186. The circuit board housing 300 may include a plurality of walls and an internal volume 304 defined within the plurality of walls. For example, the plurality of walls may include a bottom wall 306 (see, e.g., FIGS. 4-6), a front side wall 308, a left side wall 310, a back side wall 312, and a right side wall 314. The circuit board housing 300 may be open at a top side, such that the internal volume 304 is accessible via the top of the circuit board housing 300. The circuit board 302 may be secured within the circuit board housing 300, e.g., by a combination of tabs 336, snaps 338, and fasteners 344 (see, e.g., FIGS. 9 and 13), such as one or more tabs 336, one or more snaps 338, and/or at least one fastener 344. For example, FIG. 10 provides an enlarged perspective view of an exemplary snap 338 with the circuit board 302 retained by the snap 338 and below the snap 338 in a fully assembled configuration.

Also as may be seen in FIG. 3, the circuit board housing 302 may include one or more keep out features 318, such as a rib or set of ribs, at and around a fastener location. For example, the keep out feature(s) 318 may be provided to prevent or reduce damage to the circuit board 302 when installing the circuit board 302 into the circuit board housing 300, such as may occur if a driver slips while installing a fastener, e.g., screw, to assemble the circuit board 302 to the circuit board housing 300. Accordingly, the keep out feature(s) 318 may be positioned and configured to guide and limit the motion of the screw (or other fastener) and driver to reduce or prevent inadvertent touching of the circuit board 302 with the driver. In various embodiments, the keep out feature(s) 318 may be integrally joined with the circuit board housing 300, e.g., molded into the circuit board housing 300, along the perimeter of the circuit board housing 300, such as along an edge or at a corner.

In particular, the keep out feature(s) 318 may be integrally joined and/or integrally formed with one or more other components of the circuit board housing 300, e.g., one or more of the side walls 308, 310, 312, and/or 314. For example, the circuit board housing 300, including the keep out feature(s) 318, may comprise a plastic material or other similar molded material, and the keep out feature(s) 318 may be molded into one or more adjoining components, such as one of the side walls. For example, the keep out feature(s) 318 may be molded with an undercut, thus allowing the circuit board 302 to slide under the keep out feature(s) 318. An additional mounting feature, such as a boss 320, may be situated below the keep out feature 318 (or an additional mounting feature may be situated below each keep out feature 318 when more than one keep out feature is provided. For example, the boss 320, such as an internally threaded portion thereof, may be concentric to the keep out feature 318, such that, when assembled, the circuit board 302 board is sandwiched between the keep out feature 318 and the additional mounting feature, e.g., the boss 320, with the keep out feature 318 above and extending at least partially around the boss 320, such as surrounding the boss 320.

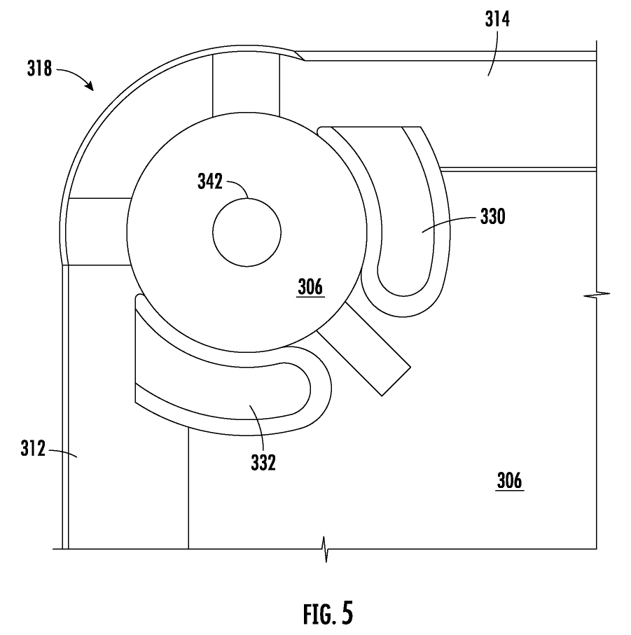

FIGS. 4 and 5 provide enlarged views of a corner of the circuit board housing 300. In particular, FIG. 4 provides a perspective view of a top side of the corner of the circuit board housing 300 and FIG. 5 provides a bottom view of the corner of the circuit board housing 300. As may be seen, e.g., in FIGS. 4 and 5, in some embodiments, the keep out feature 318 may be or may include at least one rib, such as two curved, e.g., semi-cylindrical, ribs 330 and 332. As mentioned above, an undercut may be provided whereby the circuit board 302 is positionable between the keep out feature 318 and the boss 320. For example, as illustrated in FIG. 4, an undercut 334 may be formed in a bottom portion of both ribs 330, 332. In some embodiments, a single rib may be provided, or more than two ribs may be provided to form the keep out feature or features 318. The rib (or each rib when more than one rib is provided) may have any suitable shape, e.g., such that a longitudinal axis of the rib may form a single straight line, a compound line including multiple straight line and/or curved segments, or other similar shapes.

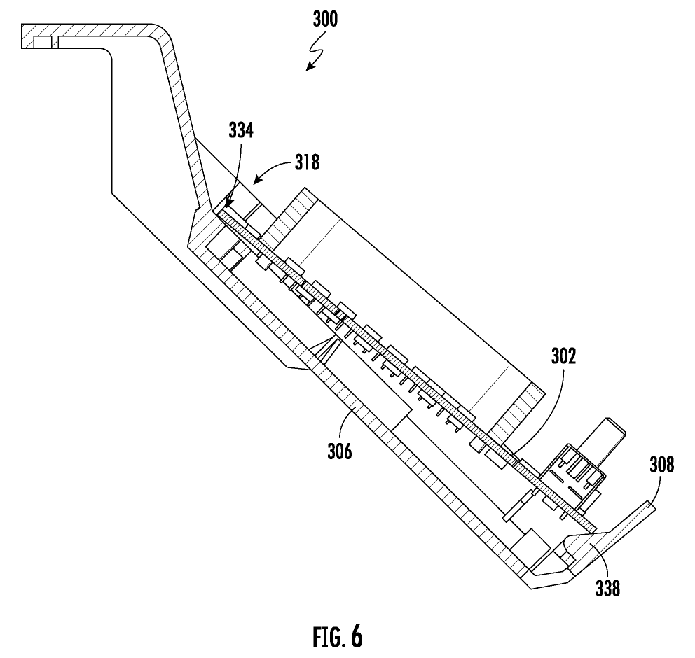

FIG. 6 illustrates the circuit board 302 in a partially assembled position in the circuit board housing 300. As shown in FIG. 6, a back edge of the circuit board 302 may be first slid under the attachment tabs 336 (see, e.g., FIG. 3) and under the keep out feature 318 (such as into the undercut 334), thus retaining a back portion, e.g., approximately half, of the circuit board 300. Once inserted under the tab(s) 336 and keep out feature 318, the circuit board 302 may then be rotated (e.g., from the position illustrated in FIG. 6) down into the circuit board housing 300, such that snaps 338 on the opposite side fully attach and retain the remainder of the circuit board 302, e.g., the other portion, e.g., approximately half, of the circuit board 302 such as the front half of the circuit board 302. The tabs 336 and snaps 338 may be on opposite sides of the circuit board housing 300, such as tabs 336 may be provided on the back side wall 312 while the snaps 338 are provided on the opposite side wall, the front side wall 308.

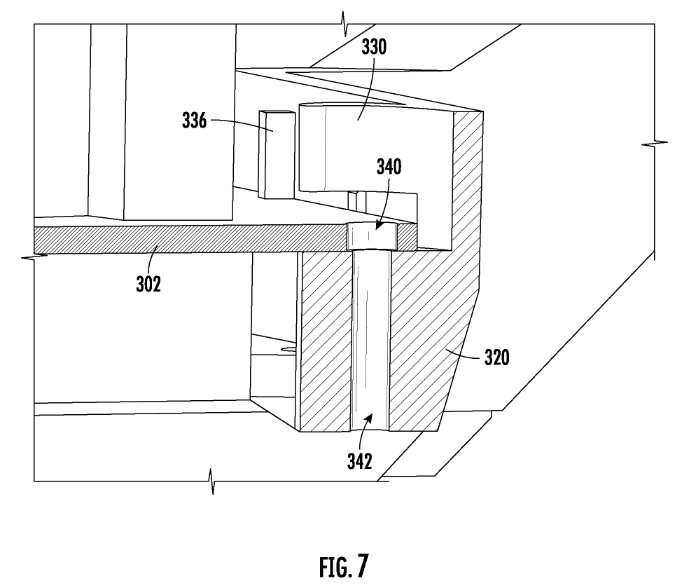

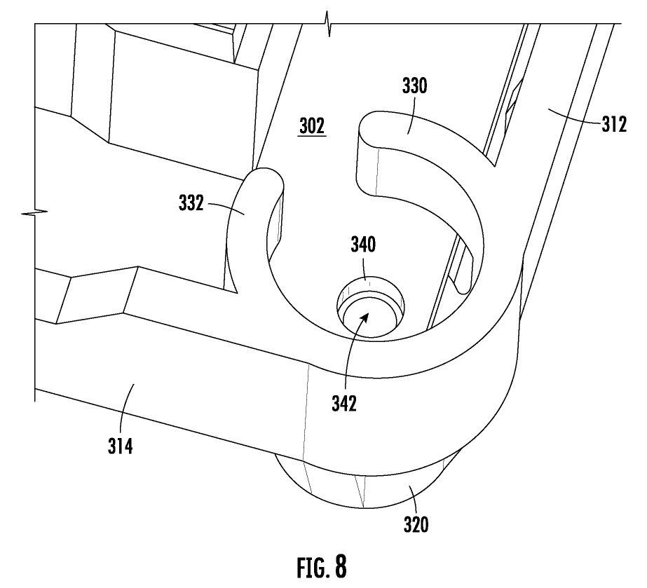

As may be seen, e.g., in FIGS. 7 and 8, the circuit board 302 may include a through hole 340. The boss 320 of the circuit board housing 300 may be configured to align with the through hole 340 when the circuit board 302 is fully installed. In particular, the boss 320 may include a bore 342 for receiving a fastener, e.g., a screw, 344. For example, the bore 342 may include internal threads for mating with external threads on a shaft 350 (FIG. 13) of the fastener 344. Accordingly, when the circuit board 302 is fully installed within the circuit board housing 300, e.g., after rotating down from the position illustrated in FIG. 6 and snapping in place as described above, the bore 342 may be aligned, such as concentric, with the through hole 340. In some embodiments, the through hole 340 and bore 342 may be generally aligned when in the fully installed position, such as generally concentric, e.g., generally aligned includes the offset from a point on the through hole 340 of the circuit board 302 to a corresponding point of the bore 342 of the boss 320 is within +/-10%, such as within +/-5%, such as within +/-4%, such as within +/-3%, such as within +/-2%, such as within +/-1%, such as within +/-0.5% of the overall dimension of the through hole 340, e.g., the diameter of the through hole 340. For example, the corresponding points of the bore 342 and through hole 340 may be centers of each of the bore 342 and the through hole 340, such that the hole 340 and bore 342 may be generally concentric in that the respective center points may be within any of the stated percentage ranges of the diameter of the through hole 340 from each other.

When the through hole 340 in the circuit board 302 and the bore 342 of the boss 320 are generally aligned, e.g., generally concentric, as described, a mechanical fastener may be used to secure the circuit board 302 in the fully installed position within the circuit board housing 302. For example, the fastener 344 may be a screw, e.g., as illustrated in FIG. 9. The fastener, e.g., screw, 344 may extend through the through hole 340 in the circuit board 302 and into the boss 320, such as into the bore 342 in the boss 320. The circuit board 302 may thus be retained in the circuit board housing 300 by the mechanical fastener 344. Moreover, as discussed above, the keep out feature 318 may prevent or reduce a driver from impacting the circuit board 302 during installation of the fastener 344, such as if the driver slips out of engagement with the fastener, the keep out feature may intercept the driver before it can over travel into contact with the circuit board 302.

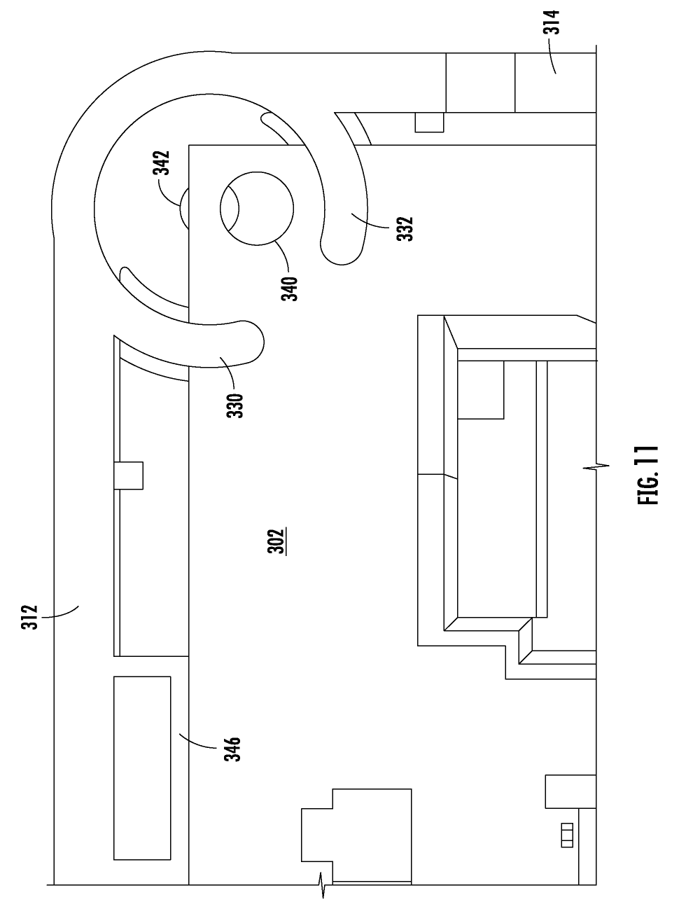

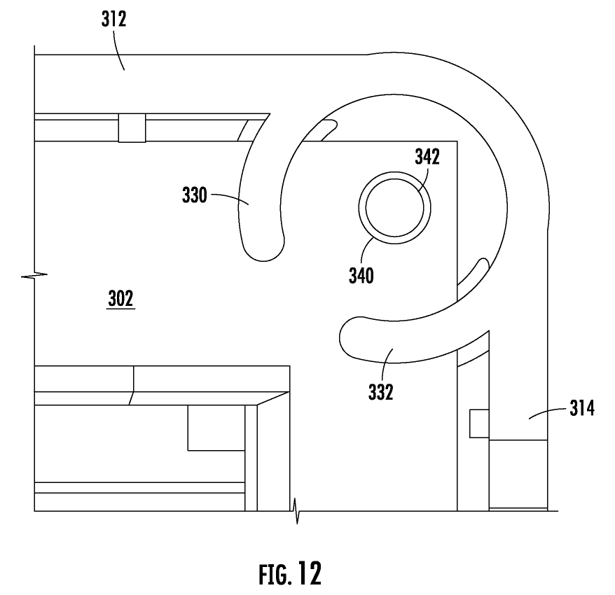

Referring now to FIGS. 11 and 12, in some embodiments, the circuit board housing 300 may also include a flexible member 346. For example, the flexible member may be formed of the same material as the circuit board housing 300, e.g., the side walls thereof, and may be integrally joined with one or more of the side walls. The flexible member 346 may be comprised of a relatively thin section of material, e.g., to impart a flexible or spring-like quality to the flexible member 346. Thus, the flexible member 346 may be positioned and configured to bias the circuit board 302 away from the fully installed position within the circuit board housing 300, e.g., as illustrated in FIG. 11, where the through hole 340 and the bore 342 are not substantially aligned. The flexible member 346 may thusly provide positive feedback during installation to promote fully inserting the circuit board 302 into the circuit board housing 300 before securing the circuit board 302 with the fastener 344. That is, some force may be required to compress the flexible member 346 as the circuit board 302 moves into the fully assembled position within the circuit board housing 300, thereby reducing the likelihood of the bore 342 and the through hole 340 being aligned before the circuit board 302 is fully installed, e.g., below both the tabs 336 and snaps 338 on multiple sides (such as opposite sides as described above) of the circuit board 302, and with the through hole 340 and the bore 342 aligned.

In some embodiments, one or more fasteners may be provided to secure the circuit board 302 without extending through the circuit board 302. For example, as illustrated in FIG. 13, the fastener 344 may include a head 348 and a shaft 350, e.g., an externally threaded shaft as illustrated in FIG. 13, which extends into the boss 320 (e.g., which may be internally threaded as mentioned above) when the circuit board 302 is installed in the circuit board housing 300. In such embodiments, the circuit board 302 may be secured between the fastener 344 and the boss 320, such as with an external edge 352 of the circuit board 302 between the head 348 of the fastener 344 and the boss 320, such that the circuit board 302 is retained in the circuit board housing 300 by the mechanical fastener 344.

As shown and described herein, provided is a circuit board assembly for a household appliance which includes a circuit board housing 300 and a circuit board 302. The circuit board housing 300 may be mounted within a cabinet of the household appliance. The circuit board housing 300 includes a plurality of walls and an internal volume 304 defined within the plurality of walls. The circuit board 302 may be retained in the internal volume 304 of the circuit board housing 300 between the plurality of walls. The circuit board housing 300 may include a rib 330 integrally joined with one wall of the plurality of walls and the circuit board 302 may be retained within the internal volume 304 of the circuit board housing 300 below the rib 330.

The rib 330 may take various forms and more than one rib 330 may be provided in some embodiments of the present disclosure. For example, the rib 330 may be cylindrical or partially cylindrical, such as a single rib which extends continuously from a first end integrally joined to one of the side walls 308, 310, 312, 314 of the circuit board housing 300 to a second end integrally to one of the side walls 308, 310, 312, 314 (either the same wall as the first end or an adjoining wall), or one or more partially cylindrical ribs may be provided which extend from a first end integrally joined to one of the side walls 308, 310, 312, 314 of the circuit board housing 300 to a free end spaced apart from the walls of the circuit board housing 300. For example, as may be seen in FIGS. 3-5, 7-9, 11, and 12, and as mentioned above, the keep out feature 318 may include two curved ribs 330 and 332.

In some embodiments, the keep out feature 318 may be provided at a corner of the circuit board housing 300, e.g., with the first rib 330 integrally joined to back side wall 312 and the second rib integrally joined to an adjoining side wall, e.g., the right side wall 314. In additional embodiments, the keep out feature 318 may also or instead be provided closer to a center of the circuit board housing 300 and/or circuit board 302 therein, such as the keep out feature may be integrally joined to one of the side walls 308, 310, 312, 314 of the circuit board housing 300 by an arm, such as with a living hinge at a first end of the arm integrally joined to the side wall and the keep out feature 318, e.g., at least one rib, integrally formed at a second end of the arm.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

What is claimed is:

1. A household appliance comprising:
a cabinet;
a circuit board housing mounted within the cabinet, the circuit board housing comprising a plurality of walls, an internal volume defined within the plurality of walls, a keep out feature, and a boss configured to receive a fastener; and
a circuit board retained in the internal volume of the circuit board housing between the plurality of walls,
wherein the keep out feature comprises a rib integrally joined with one wall of the plurality of walls, the rib configured to permit access by a driver to the boss of the housing while limiting access by the driver to the circuit board.

2. The household appliance of claim 1, wherein the circuit board is retained within the internal volume of the circuit board housing below the rib.

3. The household appliance of claim 1, wherein the rib is positioned above and extends at least partially around the boss.

4. The household appliance of claim 1, wherein the circuit board comprises a through hole, the through hole aligned with the boss, further comprising a mechanical fastener extending through the through hole in the circuit board and into the boss, whereby the circuit board is retained in the circuit board housing by the mechanical fastener.

5. The household appliance of claim 1, further comprising a mechanical fastener joined to the boss, wherein an external edge of the circuit board is positioned between a head of the mechanical fastener and the boss, whereby the circuit board is retained in the circuit board housing by the mechanical fastener.

6. The household appliance of claim 1, wherein the rib is positioned at a corner of the circuit board housing.

7. The household appliance of claim 1, wherein the rib is a first rib, further comprising a second rib integrally joined with one wall of the plurality of walls.

8. The household appliance of claim 1, wherein the rib is curved.

9. The household appliance of claim 1, further comprising a flexible member integrally joined with one wall of the plurality of walls, wherein the flexible member is positioned and configured to bias the circuit board away from an installed position when the circuit board is not fully installed.

10. A circuit board assembly for a household appliance, the household appliance comprising a cabinet, the circuit board assembly comprising:
a circuit board housing configured to be mounted within the cabinet, the circuit board housing comprising a plurality of walls, an internal volume defined within the plurality of walls, a keep out feature, and a boss configured to receive a fastener; and
a circuit board retained in the internal volume of the circuit board housing between the plurality of walls,
wherein the keep out feature comprises a rib integrally joined with one wall of the plurality of walls, the rib configured to permit access by a driver to the boss of the housing while limiting access by the driver to the circuit board.

11. The assembly of claim 10, wherein the circuit board is retained within the internal volume of the circuit board housing below the rib.

12. The assembly of claim 10, wherein the rib is positioned above and extends at least partially around the boss.

13. The assembly of claim 10, wherein the circuit board comprises a through hole, the through hole aligned with the boss, further comprising a mechanical fastener extending through the through hole in the circuit board and into the boss, whereby the circuit board is retained in the circuit board housing by the mechanical fastener.

14. The assembly of claim 10, further comprising a mechanical fastener joined to the boss, wherein an external edge of the circuit board is positioned between a head of the mechanical fastener and the boss, whereby the circuit board is retained in the circuit board housing by the mechanical fastener.

15. The assembly of claim 10, wherein the rib is positioned at a corner of the circuit board housing.

16. The assembly of claim 10, wherein the rib is a first rib, further comprising a second rib integrally joined with one wall of the plurality of walls.

17. The assembly of claim 10, wherein the rib is curved.

18. The assembly of claim 10, further comprising a flexible member integrally joined with one wall of the plurality of walls, wherein the flexible member is positioned and configured to bias the circuit board away from an installed position when the circuit board is not fully installed.
